(19) United States
(12) Patent Application Publication
(10) Pub. No.: US 2012/0161087 A1
(43) Pub. Date: Jun. 28, 2012

(54) Photosensitive Resin Composition and Color Filter Using the Same

(75) Inventors: Ju-Ho Jung, Uiwang-si (KR); Ji-Yun Kwon, Uiwang-si (KR); In-Jae Lee, Uiwang-si (KR); Dong-Wan Kim, Uiwang-si (KR); Jae-Hyun Kim, Uiwang-si (KR); Dong-Won Song, Uiwang-si (KR); Gyu-Seok Han, Uiwang-si (KR); Han-Chul Hwang, Uiwang-si (KR)

(73) Assignee: CHEIL INDUSTRIES INC., Gumi-si (KR)

(21) Appl. No.: 13/197,194

(22) Filed: Aug. 3, 2011

(30) Foreign Application Priority Data
Dec. 27, 2010 (KR) 10-2010-0135699

(51) Int. Cl. G03F 7/028; G02B 5/23; G03F 7/038

(52) U.S. Cl. 252/586; 430/286.1

(57) ABSTRACT

A photosensitive resin composition for a color filter including a colorant including a dye represented by the following Chemical Formula 1, (B) an acrylic-based binder resin, (C) a photopolymerizable monomer, (D) a photopolymerization initiator, and (E) a solvent, and a color filter using the same are provided.

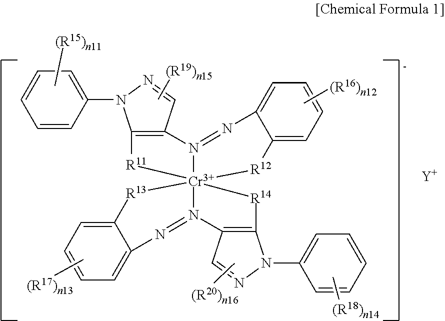

In Chemical Formula 1, each substituent is the same as defined in the detailed description.

### CROSS-REFERENCE TO RELATED APPLICATION

This application claims priority under 35 USC Section 119 to and the benefit of Korean Patent Application No. 10-2010-0135699 filed in the Korean Intellectual Property Office on Dec. 27, 2010, the entire disclosure of which is incorporated herein by reference.

### FIELD OF THE INVENTION

The present invention relates to a photosensitive resin composition and a color filter using the same.

### BACKGROUND

Color filters are used in liquid crystal displays (LCDs), optical filters for cameras, and the like. Color filters may be fabricated by coating a fine region with three or more colors on a charge-coupled device or a transparent substrate. The colored thin film can be fabricated by dyeing, printing, electrophoretic deposition (EPD), pigment dispersion, and the like.

The pigment dispersion method forms a colored film by repeating a series of processes such as coating, exposing to a light, developing, and curing a photopolymer composition including a coloring agent on a transparent substrate including a black matrix. The pigment dispersion method can improve heat resistance and durability, which are very important characteristics for a color filter, and can provide a film with a uniform thickness.

However, in the pigment dispersion method, the pigment may be not dissolved in a solvent and thus may remain as a dispersion. Accordingly, the pigment dispersion method can be limited with regard to improving the color characteristics of contrast ratio since the pigment particles may reflect, diffract, refract, or interfer with light when light is transmitted.

### SUMMARY

One embodiment of the present invention provides a photosensitive resin composition for a color filter that can have a high contrast ratio, high luminance, and excellent durability.

Another embodiment of the present invention provides a color filter using the photosensitive resin composition for a color filter.

According to one embodiment of the present invention, a photosensitive resin composition for a color filter of the present invention includes (A) a colorant including a dye represented by the following Chemical Formula 1; (B) an acrylic-based binder resin; (C) a photopolymerizable monomer; (D) a photopolymerization initiator; and (E) a solvent.

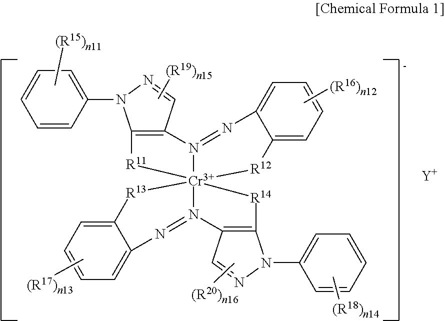

In Chemical Formula 1,

R¹¹ to R¹⁴ are the same or different and are independently a single bond or oxygen,

R¹⁵ to R²⁰ are the same or different and are independently hydrogen, hydroxyl, substituted or unsubstituted amine, nitro, substituted or unsubstituted C1 to C20 alkoxy, substituted or unsubstituted C1 to C20 alkyl, substituted or unsubstituted C2 to C20 alkenyl, substituted or unsubstituted C2 to C20 alkynyl, substituted or unsubstituted C3 to C20 cycloalkyl, substituted or unsubstituted C3 to C20 cycloalkenyl, substituted or unsubstituted C3 to C20 cycloalkynyl group, substituted or unsubstituted C2 to C20 heterocycloalkyl, substituted or unsubstituted C2 to C20 heterocycloalkenyl, substituted or unsubstituted C2 to C20 heterocycloalkynyl, substituted or unsubstituted C6 to C30 aryl, or substituted or unsubstituted C6 to C30 aryloxy,

n¹¹ to n¹⁶ are the same or different and are independently integers ranging from 0 to 4, and

Y is Na, K, Ca, Mg, Al, Zn, or Fe.

The dye of the above Chemical Formula 1 may include a compound represented by the following Chemical Formula 2.

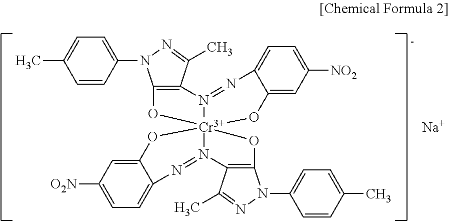

The dye may have a solubility in a solvent of about 3 to about 20, a maximum absorption wavelength at about 400 to about 460 nm wavelength region, transmittance of about 85 to about 100% at about 500 to about 800 nm wavelength region, and a thermal decomposition temperature of about 150 to about 400° C.

The colorant may further include a pigment.

The colorant may include the dye and the pigment at a weight ratio of about 1:9 to about 9:1:

The photosensitive resin composition for a color filter may include about 1 to about 30 wt % of the colorant; about 1 to about 30 wt % of the acrylic-based binder resin; about 1 to about 15 wt % of the photopolymerizable monomer; about 0.1 to about 10 wt % of the photopolymerization initiator; and balance of the solvent.

The acrylic-based binder resin may include a copolymer of a first ethylenic unsaturated monomer such as but not limited to (meth)acrylic acid, maleic acid, itaconic acid, fumaric acid, or a combination thereof; and a second ethylenic unsaturated monomer such as but not limited to styrene, α-methylstyrene, vinyltoluene, vinylbenzylmethylether, methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, 2-aminoethyl(meth)acrylate, 2-dimethylaminoethyl(meth)acrylate, vinyl actate, vinyl benzoate, glycidyl(meth)acrylate, (meth)acrylonitrile, (meth)acrylamide, or a combination thereof.

The photopolymerizable monomer may include without limitation ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, or a combination thereof.

The photosensitive resin composition for a color filter may further include one or more additives such as but not limited to malonic acid; 3-amino-1,2-propanediol; a silane-based coupling agent including a vinyl group or a (meth)acryloxy group; a leveling agent; a fluorine-based surfactant; a radical polymerization initiator; or a combination thereof.

According to another embodiment of the present invention a color filter manufactured using the photosensitive resin composition is provided.

Hereinafter, other embodiments will be described in detail.

The photosensitive resin composition for a color filter can have a high contrast ratio and high luminance, and excellent durability, and therefore can be used in the production of a color filter.

### DETAILED DESCRIPTION

The present invention will be described more fully hereinafter in the following detailed description of the invention, in which some but not all embodiments of the invention are described. Indeed, this invention may be embodied in many different forms and should not be construed as limited to the embodiments set forth herein; rather, these embodiments are provided so that this disclosure will satisfy applicable legal requirements.

As used herein, when a specific definition is not otherwise provided, the term “substituted” refers to one substituted with a substituent including halogen (F, Cl, Br or I), hydroxyl, C1 to C20 alkoxy, nitro, cyano, amine, imino, azido, amidino, hydrazino, hydrazono, carbonyl, carbamyl, thiol, ester, ether, carboxyl or a salt thereof, sulfonic acid or a salt thereof, phosphoric acid or a salt thereof, C1 to C20 alkyl, C2 to C20 alkenyl, C2 to C20 alkynyl, C6 to C30 aryl, C3 to C20 cycloalkyl, C3 to C20 cycloalkenyl, C3 to C20 cycloalkynyl, C2 to C20 heterocycloalkyl, C2 to C20 heterocycloalkenyl, C2 to C20 heterocycloalkynyl, C3 to C30 heteroaryl, or a combination thereof, in place of at least one hydrogen.

As used herein, when a specific definition is not otherwise provided, the term “hetero” may refer to a cyclic group in which one or more hydrogen atoms are substituted with one or more heteroatoms comprising N, O, S, P, or a combination thereof.

As used herein, when a specific definition is not otherwise provided, the term “(meth)acrylate” refers to both “acrylate” and “methacrylate”, and the term “(meth)acrylic acid” refers to “acrylic acid” and “methacrylic acid”.

The photosensitive resin composition for a color filter according to one embodiment includes (A) a colorant, (B) an acrylic-based binder resin, (C) a photopolymerizable monomer, (D) a photopolymerization initiator, and (E) a solvent.

Hereinafter, each component is described in detail.

(A) Colorant

The colorant may include a dye such as an imidazole chromium complex, and the dye may be represented by the following Chemical Formula 1.

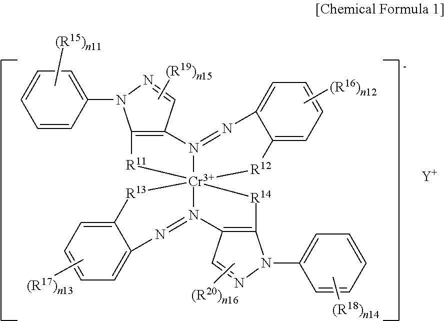

In Chemical Formula 1:

R¹¹ to R¹⁴ are the same or different and are independently a single bond or oxygen,

R¹⁵ to R²⁰ are the same or different and are independently hydrogen, hydroxyl, substituted or unsubstituted amine, nitro, substituted or unsubstituted C1 to C20 alkoxy, substituted or unsubstituted C1 to C20 alkyl, substituted or unsubstituted C2 to C20 alkenyl, substituted or unsubstituted C2 to C20 alkynyl, substituted or unsubstituted C3 to C20 cycloalkyl, substituted or unsubstituted C3 to C20 cycloalkenyl, substituted or unsubstituted C3 to C20 cycloalkynyl, substituted or unsubstituted C2 to C20 heterocycloalkyl, substituted or unsubstituted C2 to C20 heterocycloalkenyl, substituted or unsubstituted C2 to C20 heterocycloalkynyl, substituted or unsubstituted C6 to C30 aryl, substituted or unsubstituted C6 to C30 aryloxy, or a combination thereof,

n¹¹ to n¹⁶ are the same or different and are independently integers ranging from 0 to 4, and

Y is Na, K, Ca, Mg, Al, Zn, or Fe.

An example of the dye includes but is not limited to a compound represented by the following Chemical Formula 2.

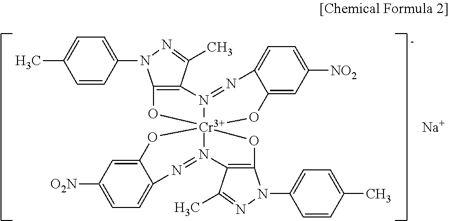

The dye may be a red dye.

The dyes of Chemical Formula 1 may be commerically available and/or may be produced using commercially available starting materials by the skilled artisan without undue experimentation.

Unlike a pigment having particles, the dye of Chemical Formula 1 can have good solubility in a solvent, and thus when dissolved in a solvent the dye has no particles or very small particles having a first particle diameter of about 1 to about 10 nm. Further, the dye of Chemical Formula 1 can have high durability. When the dye has a significantly smaller diameter than the pigment, there may be less optical scattering, which can improve contrast ratio. Thereby, the dye of Chemical Formula 1 may compensate for the deterioration of contrast ratio and luminance which has been a problem when using conventional pigment dispersion methods to fabricate a color filter.

The dye may have a solubility in a solvent of about 3 to about 20, for example about 3 to about 12. As used herein, and as will be appreciated and understood by the skilled artisan, the solubility of the dye refers to an amount (g) of the dye dissolved in about 100 g of a solvent, such as any of the solvents listed herein, at room temperature. As also will be appreciated and understood by the skilled artisan, solubility as used herein is not expressed in terms of a specific unit.

When the dye has a solubility within the above range, the dye may not decompose and further may provide excellent coloring properties and compatibility with other components of the photosensitive resin composition for a color filter.

The dye may have a maximum absorption wavelength at about 400 to about 460 nm wavelength region during spectroscopic analysis. The dye may also have a transmittance of about 85 to about 100% at about 500 to about 800 nm wavelength region during spectroscopic analysis. When the dye has a maximum absorption wavelength and a transmittance within the above ranges, it may have high luminance.

The dye can have a high heat resistance. In other words, the thermal decomposition temperature of the dye may range from about 150 to about 400° C. as measured by a thermogravimetric analyzer (TGA).

The dye having these characteristics can have a high luminance and a high contrast ratio in the desirable color coordinate, and it may be used in the production of a LCD color filter including a backlight of a CCFL or a LED.

The photosensitive resin composition for a color filter may further include another dye, such as a yellow dye, in addition to or instead of the red dye.

According to one embodiment, the colorant may include only the dye or may include a dye mixed with a pigment for improving durability.

The pigment may include a red pigment, a yellow pigment, or a combination thereof.

The red pigment may include a compound having at least one azo group. Examples of the red pigment may include without limitation C.I. pigment red 254, C.I. pigment red 242, C.I. pigment red 214, C.I. pigment red 221, C.I. pigment red 166, C.I. pigment red 220, C.I. pigment red 248, C.I. pigment red 262, and the like, and combinations thereof.

Examples of the yellow pigment may include without limitation C.I. pigment yellow 139, C.I. pigment yellow 138, C.I. pigment yellow 150, and the like, and combinations thereof.

For example, the colorant may be prepared by mixing the dye and the pigment at a weight ratio of about 1:9 to about 9:1 or at a weight ratio of about 3:7 to about 7:3. In some embodiments, the mixture of the dye and the pigment may include the dye in an amount of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of dye in the mixture of the dye and the pigment can be in a range from about any of the foregoing amounts to about any other of the foregoing amounts.

In some embodiments, the mixture of the dye and the pigment may include the pigment in an amount of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of the pigment in the mixture of the dye and the pigment can be in a range from about any of the foregoing amounts to about any other of the foregoing amounts.

When the dye and the pigment are mixed at the above weight ratio range, they may provide a high contrast ratio while maintaining the color characteristics.

The photosensitive resin composition may include the colorant in an amount of about 1 to about 30 wt %, for example, about 3 to about 25 wt %, based on the total weight of the photosensitive resin composition for a color filter. In some embodiments, the photosensitive resin composition may include the colorant in an amount of about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 wt %. Further, according to some embodiments of the present invention, the amount of the colorant can be in a range from about any of the foregoing amounts to about any other of the foregoing amounts. When the colorant is included in an amount within the above range, it may provide excellent color characteristics and high contrast ratio in the same color coordinate.

(B) Acrylic-Based Binder Resin

The acrylic-based binder resin is a copolymer of a first ethylenic unsaturated monomer and a second ethylenic unsaturated monomer that is copolymerizable with the first ethylenic unsaturated monomer, and a resin including at least one acrylic-based repeating unit.

The first ethylenic unsaturated monomer is an ethylenic unsaturated monomer including at least one carboxyl group. Examples of the monomer include without limitation acrylic acid, methacrylic acid, maleic acid, itaconic acid, fumaric acid, and the like, and combinations thereof.

The copolymer may include the first ethylenic unsaturated monomer in an amount ranging from about 5 to about 50 wt %, for example, from about 10 to about 40 wt %, based on the total weight of the acrylic-based binder resin. In some embodiments, the copolymer may include the first ethylenic unsaturated monomer in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %. Further, according to some embodiments of the present invention, the amount of the first ethylenic unsaturated monomer can be in a range from about any of the foregoing amounts to about any other of the foregoing amounts.

Examples of the second ethylenic unsaturated monomer may include without limitation aromatic vinyl compounds such as styrene, α-methylstyrene, vinyltoluene, vinylbenzylmethylether, and the like; unsaturated carboxylic acid ester compounds such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, and the like; unsaturated carboxylic acid amino alkyl ester compounds such as 2-aminoethyl(meth)acrylate, 2-dimethylaminoethyl(meth)acrylate, and the like; a carboxylic acid vinyl ester compound such as vinyl acetate, vinyl benzoate, and the like; unsaturated carboxylic acid glycidyl ester compounds such as glycidyl(meth)acrylate and the like; vinyl cyanide compounds such as (meth)acrylonitrile and the like; unsaturated amide compounds such as (meth)acrylamide and the like; and the like, and combinations thereof.

Examples of the acrylic-based binder resin may include without limitation a methacrylic acid/benzylmethacrylate copolymer, a methacrylic acid/benzylmethacrylate/styrene copolymer, a methacrylic acid/benzylmethacrylate/2-hydroxyethylmethacrylate copolymer, a methacrylic acid/benzylmethacrylate/styrene/2-hydroxyethylmethacrylate copolymer, and the like, and combinations thereof.

The acrylic-based binder resin may have a weight average molecular weight ranging from about 3,000 to about 150,000 g/mol, for example about 5,000 to about 50,000 g/mol, and as another example about 2,000 to about 30,000 g/mol. When the acrylic-based binder resin has a weight average molecular weight within the above range, the photosensitive resin composition can have improved physical and chemical properties and suitable viscosity, which can improve close contacting (adhesion) properties with a substrate during fabrication of a color filter.

The acrylic-based binder resin may have an acid value ranging from about 15 to about 60 mgKOH/g, for example about 20 to about 50 mgKOH/g. When the acrylic-based binder resin has an acid value within the above range, excellent pixel resolution may be realized.

The photosensitive resin composition may include the acrylic-based binder resin in an amount of about 1 to about 30 wt %, for example about 5 to about 20 wt %, based on the total weight of the photosensitive resin composition for a color filter. In some embodiments, the photosensitive resin composition may include the acrylic-based binder resin in an amount of about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 wt %. Further, according to some embodiments of the present invention, the amount of the acrylic-based binder resin can be in a range from about any of the foregoing amounts to about any other of the foregoing amounts.

When the acrylic-based binder resin is included in an amount within the above range, improved developability may be provided during manufacture of a color filter, and the cross-linking property can be improved to obtain excellent smooth surface properties.

(C) Photopolymerizable Monomer

The photopolymerizable monomer may be a mono-functional or multi-functional ester of (meth)acrylic acid including at least one ethylenic unsaturated double bond.

The photopolymerizable monomer can promote sufficient polymerization when the composition is exposed during pattern forming processes to form patterns having excellent heat resistance, light resistance, and chemical resistance, due to the ethylenic unsaturated double bond.

Examples of the photopolymerizable monomer include without limitation ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like, and combinations thereof.

Commercially available examples of the photopolymerizable monomer are as follows. The mono-functional (meth)acrylic acid ester may include without limitation Aronix M-101®, M-111®, M-114® (TOAGOSEI CHEMICAL INDUSTRY CO., LTD.); KAYARAD TC-110S®, TC-120S® (NIPPON KAYAKU CO., LTD.); V-158®, V-2311® (OSAKA ORGANIC CHEMICAL IND., LTD.), and the like. Examples of a difunctional (meth)acrylic acid ester may include without limitation Aronix M-210®, M-240®, M-6200® (TOAGOSEI CHEMICAL INDUSTRY CO., LTD.), KAYARAD HDDA®, HX-220®, R-604® (NIPPON KAYAKU CO., LTD.), V-260®, V-312®, V-335 HP® (OSAKA ORGANIC CHEMICAL IND., LTD.), and the like. Examples of a tri-functional (meth)acrylic acid ester may include without limitation Aronix M-309®, M-400®, M-405®, M-450®, M-7100®, M-8030®, M-8060® (TOAGOSEI CHEMICAL INDUSTRY CO., LTD.), KAYARAD TMPTA®, DPCA-20®, DPCA-30®, DPCA-60®, DPCA-120® (NIPPON KAYAKU CO., LTD.), V-295®, V-300®, V-360®, V-GPT®, V-3PA®, V-400® (Osaka Yuki Kayaku Kogyo Co. Ltd.), and the like. The photopolymerizable monomer may be used singularly or as a mixture of two or more.

The photopolymerizable monomer may be treated with acid anhydride to improve developability.

The photosensitive resin composition may include the photopolymerizable monomer in an amount ranging from about 1 to about 15 wt %, for example about 5 to about 10 wt %, based on the total weight of the photosensitive resin composition. In some embodiments, the photosensitive resin composition may include the photopolymerizable monomer in an amount of about 1, 2, 3, 4, 5, 6, 7, 8, 9, 10, 11, 12, 13, 14, or 15 wt %. Further, according to some embodiments of the present invention, the amount of the photopolymerizable monomer can be in a range from about any of the foregoing amounts to about any other of the foregoing amounts.

When the photopolymerizable monomer is included in an amount within the above range, curing when exposed during pattern forming processes can be sufficiently performed, and alkali development property can be excellent.

(D) Photopolymerization Initiator

Examples of the photopolymerization initiator may include without limitation acetophenone-based compounds, benzophenone-based compounds, thioxanthone-based compounds, benzoin-based compounds, triazine-based compounds, oxime-based compounds, and the like, and combinations thereof.

Examples of the acetophenone-based compound may include without limitation 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like, and combinations thereof.

Examples of the benzophenone-based compound may include without limitation benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like, and combinations thereof.

Examples of the thioxanthone-based compound may include without limitation thioxanthone, 2-methylthioxanthone, isopropyl thioxanthone, 2,4-diethyl thioxanthone, 2,4-diisopropyl thioxanthone, 2-chlorothioxanthone, and the like, and combinations thereof.

Examples of the benzoin-based compound may include without limitation benzoin, benzoin methyl ether, benzoin ethyl ether, benzoin isopropyl ether, benzoin isobutyl ether, benzyldimethylketal, and the like, and combinations thereof.

Examples of the triazine-based compound may include without limitation 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, and the like, and combinations thereof.

Examples of the oxime-based compound may include without limitation 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, and the like, and combinations thereof.

The photopolymerization initiator may further include a carbazole-based compound, a diketone-based compound, a sulfonium borate-based compound, a diazo-based compound, an imidazole-based compound, a biimidazole-based compound, and the like, or a combination thereof.

The photosensitive resin composition may include the photopolymerization initiator in an amount of about 0.1 to about 10 wt %, for example about 0.5 to about 5 wt %, based on the total weight of the photosensitive resin composition. In some embodiments, the photosensitive resin composition may include the photopolymerization initiator in an amount of about 0.1, 0.2, 0.3, 0.4, 0.5, 0.6, 0.7, 0.8, 0.9, 1, 2, 3, 4, 5, 6, 7, 8, 9, or 10 we/o. Further, according to some embodiments of the present invention, the amount of the photopolymerization initiator can be in a range from about any of the foregoing amounts to about any other of the foregoing amounts.

When the photopolymerization initiator is included in an amount within the above range, the composition can be sufficiently cured when exposed during pattern forming processes with minimal or no deterioration of transmittance due to non-reacted initiators.

(E) Solvent

The solvent is compatible with the dye, pigment, acrylic-based binder resin, photopolymerizable monomer, and photopolymerization initiator but does not react therewith.

Examples of the solvent may include without limitation alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbon such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl ester such as ethyl acetate, n-butyl acetate, isobutyl acetate, and the like; lactic acid alkyl esters such as methyl lactate, ethyl lactate, and the like; hydroxyacetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl esters such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate; ketonic acid esters such as ethyl pyruvate; and the like, and combinations thereof. Furthermore, the solvent may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like. These solvents may be used singularly or in combination.

Taking into consideration miscibility and reactivity, the solvent can include glycol ethers such as ethylene glycol monoethylether, and the like; ethylene glycol alkylether acetates such as ethyl cellosolve acetate, and the like; esters such as 2-hydroxy ethyl propionate, and the like; diethylene glycols such as diethylene glycol monomethylether, and the like; propylene glycol alkylether acetates such as propylene glycol methylether acetate, propylene glycol propylether acetate, and the like, and combinations thereof.

The solvent may be used in a balance amount. In exemplary embodiments, the photosensitive resin composition may include the solvent in an amount of about 20 to about 90 wt % based on the total weight of the photosensitive resin composition. In some embodiments, the photosensitive resin composition may include the solvent in an amount of about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of the solvent can be in a range from about any of the foregoing amounts to about any other of the foregoing amounts.

When the solvent is included in an amount within the above range, the photosensitive resin composition may have good coating properties and can provide a film having a thickness of 3 μm or more with excellent flatness.

(F) Other Additive(s)

The photosensitive resin composition for a color filter may further include one or more other additives such as but not limited to malonic acid; 3-amino-1,2-propanediol; a silane-based coupling agent including a vinyl group or a (meth)acryloxy group; a leveling agent; a fluorine-based surfactant; a radical polymerization initiator; and the like, and combinations thereof, to prevent stains, improve leveling performance, and also prevent residues from being generated due to undevelopment. The amount of these additives may be readily determined by the skilled artisan without undue experimentation, and the amounts may vary depending on the desired composition properties.

Examples of the silane-based coupling agent may include without limitation trimethoxysilyl benzoate, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-(3,4-epoxycyclohexyl)ethyltrimethoxysilane, and the like, and combinations thereof.

Examples of the fluorine-based surfactant may include without limitation BM-1000®, and BM-1100® (BM Chemie Inc.); MEGAFACE F 142D®, F 172®, F 173®, and F 183® DAINIPPON INK KAGAKU KOGYO CO., LTD.); FULORAD FC-135®, FULORAD FC-170C®, FULORAD FC-430®, and FULORAD FC-431® (SUMITOMO 3M CO., LTD.); SURFLON S-112®, SURFLON S-113®, SURFLON S-131®, SURFLON S-141®, and SURFLON S-145® (ASAHI GLASS CO., LTD.); and SH-28PA®, SH-190®, SH-193®, SZ-6032®, and SF-8428®, and the like (TORAY SILICONE CO., LTD.), and combinations thereof.

The photosensitive resin composition may further include an epoxy compound in order to improve close contacting properties with a substrate.

Examples of the epoxy compound include without limitation phenol novolac epoxy compounds, tetramethyl biphenyl epoxy compounds, bisphenol A epoxy compounds, alicyclic epoxy compounds, and the like and combinations thereof.

The photosensitive resin composition may include the epoxy compound in an amount of about 0.01 to about 5 parts by weight, for example about 0.1 to about 5 parts by weight, based on about 100 parts by weight of the photosensitive resin composition. When the epoxy compound is included in an amount within the above range, close contacting properties, heat resistance, and chemical resistance may be improved.

According to another embodiment, a color filter manufactured using the photosensitive resin composition is provided. The color filter can be manufactured as follows.

The photosensitive resin composition can be coated to a thickness of about 3.1 to about 3.4 μm on a bare glass substrate or a glass substrate having an about 500 Å to about 1500 Å thick SiNₓ layer (protective layer) thereon by a method such as but not limited to spin coating, slit coating, and the like. After the coating step, the coating can be exposed to radiation (irradiated by light) to form a pattern required for a color filter. When the coating layer is treated with an alkali development solution to dissolve the non-radiated part, a pattern for a color filter is formed. This process can be repeated as many times as necessary, depending on the numbers of colors of R, G, B and a light blocking layer needed to provide a color filter with a desired pattern.

In this process, the developed image pattern can be heated or cured by actinic rays to improve crack resistance, solvent resistance, and the like.

The following examples illustrate the present invention in more detail. However, it is understood that the present invention is not limited by these examples.

(Preparation of Photosensitive Resin Composition for Color Filter)

Components for preparing the photosensitive resin composition for a color filter are as follows:

(A) Colorant

(A-1) A dye represented by the following Chemical Formula 2 (manufactured by KISCO, R91006) is used.

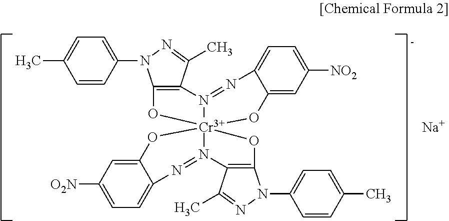

(A-2) Pigment Dispersion

The following pigment dispersions (A-2a) and (A-2b) are mixed at a weight ratio of 6:4 and used.

(A-2a) CHR50-R254 (manufactured by MIKUNI, pigment solid of 14.75 wt %)

(A-2b) CHR50-R177 (manufactured by MIKUNI, pigment solid of 12.88 wt %)

(C) Acrylic-Based Binder Resin

An acrylic acid/benzylmethacrylate copolymer (manufactured by Miwon Commercial Co., Ltd., NPR1520) is used.

(D) Photopolymerizable Monomer

Dipentaerythritol hexaacrylate is used.

(E) Photopolymerization Initiator

CGI-124 manufactured by Ciba Specialty Chemical Co., Ltd. is used.

(F) Solvent

Propylene glycol monomethyl ether acetate and ethyl 3-ethoxypropionate are used.

(G) Surfactant

A fluorine-based surfactant (F-475, manufactured by DIC) is used.

### Example 1

1.7 g of the photopolymerization initiator is dissolved in a solvent including 30.4 g of propylene glycol monomethyl ether acetate and 17.0 g of 3-ethoxy ethyl propionate and agitated at a room temperature for 2 hours. Then it is added with 9.0 g of dye represented by Chemical Formula 2, 3.5 g of the acrylic-based binder resin, and 8.5 g of the photopolymerizable monomer and agitated at a room temperature for 2 hours. 29.7 g of the pigment dispersion is added thereto and agitated at a room temperature for one hour, and 0.2 g of the surfactant is added thereto and agitated at a room temperature for one hour. The solution is filtered for three times to remove impurities and to provide a photosensitive resin composition for a color filter.

### Example 2

A photosensitive resin composition for a color filter is prepared in accordance with the same procedure as in Example 1, except that 1.2 g of the dye and 37.5 g of the dye dispersion are used.

### Comparative Example 1

A photosensitive resin composition for a color filter is prepared in accordance with the same procedure as in Example 1, except that 38.7 g of the dye dispersion is used and no pigment is used.

(Preparation of Filter for Color Filter)

Each photosensitive resin composition obtained from Examples 1 and 2 and Comparative Example 1 is coated on a degreased 1 mm-thick glass substrate to a thickness of 2 μm and dried on a hot plate of 90° C. for 2 minutes to provide a coating layer. Using a high pressure mercury lamp having a wavelength of 365 nm, the coating layer is exposed and dried in a dry oven at 160° C. for 20 minutes to provide a pattern for a color filter.

Assessment 1: Luminance and Contrast Ratio

The color coordinate and luminance and contrast ratio are measured using the obtained pattern for a color filter in accordance with the following methods, and the results are shown in the following Table 1.

(1) Color coordinates (x and y) and luminance (Y) measurements: measured using a spectrophotometer (manufactured by Otsuka Electronic Co., MCPD 3000).

(2) Contrast ratio measurement: measured using a contrast ratio measurer (manufactured by Tsubosaka electronic, CT-1, 30,000:1).

TABLE 1

| | Color coordinate | | Luminance | |
|---|---|---|---|---|
| | X | y | Y | Contrast ratio |
| Example 1 | 0.651 | 0.325 | 18.6 | 16,800 |
| Example 2 | 0.651 | 0.325 | 18.4 | 16,050 |
| Comparative | 0.651 | 0.325 | 18.3 | 15,300 |
| Example 1 | | | | |

As shown in Table 1, Examples 1 and 2 including colorants according to one embodiment have higher luminance and contrast ratio than Comparative Example 1.

Although not wishing to be bound by any explanation or theory of the invention, it is currently believed that the high luminance results from increasing the amount of high transmitting pigment due to the high color representation of dye. The high contrast ratio may be also explained as a result of decreasing unnecessary light scattering since the dye has a solubility in an organic solvent that is different from the solubility of the pigment dispersion to provide no particles or particles with a significantly smaller first diameter than the pigment in the photosensitive resin composition for a color filter.

Assessment 2: Durability

The durability is measured by using the obtained pattern for a color filter according to the following method, and the results are shown in the following Table 2.

The durability is measured according to (1) a method of dipping into a N-methylpyrrolidone (NMP) solvent at a room temperature for 30 minutes, (2) a method of dipping a mixed solvent (volume ratio=5:5) of N-methylpyrrolidone (NMP) and ethylethoxypropinonate (EEP) at 80° C. for 10 minutes, and (3) a method of exposing to a Zenon lamp with 1MJ. ΔEab* is obtained by using the color value difference between before and after the treatment. If the obtained ΔEab* value is in 3, it indicates a satisfying reliability. The less ΔEab* is, the better durability is provided.

TABLE 2

| | ΔEab* | | |
|---|---|---|---|
| | | | (C) Light |
| | (A) NMP | (B) NMP + EEP | resistance |
| Example 1 | 1.19 | 0.98 | 2.27 |
| Example 2 | 1.18 | 0.73 | 2.28 |
| Comparative | 1.21 | 1.03 | 2.31 |
| Example 1 | | | |

As shown in Table 2, Examples 1 and 2 including a colorant according to one embodiment have better durability than Comparative Example 1.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A photosensitive resin composition for a color filter comprising
(A) a colorant including a dye represented by the following Chemical Formula 1;
(B) an acrylic-based binder resin;
(C) a photopolymerizable monomer;
(D) a photopolymerization initiator; and
(E) a solvent: 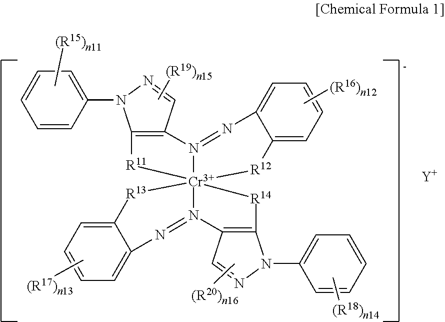
wherein, in Chemical Formula 1,
R¹¹ to R¹⁴ are the same or different and are independently a single bond or oxygen,
R¹⁵ to R²⁰ are the same or different and are independently hydrogen, hydroxyl, substituted or unsubstituted amine, nitro, substituted or unsubstituted C1 to C20 alkoxy, substituted or unsubstituted C1 to C20 alkyl, substituted or unsubstituted C2 to C20 alkenyl, substituted or unsubstituted C2 to C20 alkynyl, substituted or unsubstituted C3 to C20 cycloalkyl, substituted or unsubstituted C3 to C20 cycloalkenyl, substituted or unsubstituted C3 to C20 cycloalkynyl, substituted or unsubstituted C2 to C20 heterocycloalkyl, substituted or unsubstituted C2 to C20 heterocycloalkenyl, substituted or unsubstituted C2 to C20 heterocycloalkynyl, substituted or unsubstituted C6 to C30 aryl, or substituted or unsubstituted C6 to C30 aryloxy,
n¹¹ to n¹⁶ are the same or different and are independently integers ranging from 0 to 4, and
Y is Na, K, Ca, Mg, Al, Zn, or Fe.

2. The photosensitive resin composition for a color filter of claim 1, wherein the dye comprises a compound represented by the following Chemical Formula 2:

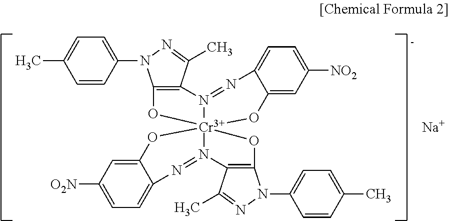

3. The photosensitive resin composition for a color filter of claim 1, wherein the dye has a solubility for a solvent of about 3 to about 20.

4. The photosensitive resin composition for a color filter of claim 1, wherein the dye has a maximum absorption wavelength at about 400 to about 460 nm wavelength region.

5. The photosensitive resin composition for a color filter of claim 1, wherein the dye has a transmittance of about 85 to about 100% at about 500 to about 800 nm wavelength region.

6. The photosensitive resin composition for a color filter of claim 1, wherein the dye has a thermal decomposition temperature of about 150 to about 400° C.

7. The photosensitive resin composition for a color filter of claim 1, wherein the colorant further comprises a pigment.

8. The photosensitive resin composition for a color filter of claim 7, wherein the colorant comprises the dye and the pigment at a weight ratio of about 1:9 to about 9:1.

9. The photosensitive resin composition for a color filter of claim 1, wherein the photosensitive resin composition for a color filter comprises
about 1 to about 30 wt % of the colorant;
about 1 to about 30 wt % of the acrylic-based binder resin;
about 1 to about 15 wt % of the photopolymerizable monomer;
about 0.1 to about 10 wt % of the photopolymerization initiator; and
balance of the solvent.

10. The photosensitive resin composition for a color filter of claim 1, wherein the acrylic-based binder resin comprises a copolymer of a first ethylenic unsaturated monomer comprising (meth)acrylic acid, maleic acid, itaconic acid, fumaric acid, or a combination thereof; and a second ethylenic unsaturated monomer comprising styrene, α-methylstyrene, vinyltoluene, vinylbenzylmethylether, methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, 2-aminoethyl(meth)acrylate, 2-dimethylaminoethyl(meth)acrylate, vinyl actate, vinyl benzoate, glycidyl(meth)acrylate, (meth)acrylonitrile, (meth)acrylamide, or a combination thereof.

11. The photosensitive resin composition for a color filter of claim 1, wherein the photopolymerizable monomer comprises ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, or a combination thereof.

12. The photosensitive resin composition for a color filter of claim 1, further comprising malonic acid; 3-amino-1,2-propanediol; a silane-based coupling agent including a vinyl group or a (meth)acryloxy group; a leveling agent; a fluorine-based surfactant; a radical polymerization initiator; or a combination thereof.

13. A color filter manufactured using the photosensitive resin composition of claim 1.
